(19) United States
(12) Patent Application Publication
(10) Pub. No.: US 2015/0253660 A1
(43) Pub. Date: Sep. 10, 2015

(54) PATTERN FORMING METHOD AND PATTERN FORMING SYSTEM

(71) Applicant: KABUSHIKI KAISHA TOSHIBA, Tokyo (JP)

(72) Inventor: Tomoko OJIMA, Tokyo (JP)

(21) Appl. No.: 14/340,650

(22) Filed: Jul. 25, 2014

(30) Foreign Application Priority Data
Mar. 6, 2014 (JP) 2014-044173

(51) Int. Cl. G03F 1/76; G03F 1/80

(52) U.S. Cl. CPC G03F 1/76; G03F 1/80

(57) ABSTRACT

According to one embodiment, a pattern forming method includes: forming a film to be processed on a substrate; forming a resist pattern on the film to be processed; irradiating a predetermined portion of the resist pattern with an energy beam; forming a reversing material layer covering the resist pattern including the portion irradiated with the energy beam; forming a reversed pattern by removing the surface of the reversing material layer so as to expose the portion of the resist pattern not irradiated with the energy beam; removing the resist pattern; and performing an etching process on the film to be processed using the reversed pattern.

### CROSS-REFERENCE TO RELATED APPLICATIONS

This application is based upon and claims the benefit of priority from Japanese Patent Application No. 2014-044173, filed on Mar. 6, 2014; the entire contents of which are incorporated herein by reference.

### FIELD

Embodiments described herein relate generally to a pattern forming method and a pattern forming system.

### BACKGROUND

During the manufacture of substrates for exposure masks, molds for imprinting, semiconductor devices, and the like, etching may be carried out using a reversed pattern.

When forming a reversed pattern, first, a reversing material layer is formed by applying reversing material so as to cover a resist pattern formed on a substrate. Next, the reversed pattern is formed from the reversing material by removing the surface of the reversing material layer so as to expose the upper surface of the resist pattern. Then, the resist pattern is removed. Then, an etching process is performed using the reversed pattern.

Here, if there is an in-plane distribution of the coverage factor of the resist pattern (the area ratio of the concave portions and the convex portions), it is difficult to form a reversing material layer with a uniform thickness.

Therefore, a dummy pattern is disposed to reduce the in-plane distribution in the coverage factor of the resist pattern so that the thickness of the reversing material layer becomes more uniform, or the reversing material is applied thicker so that the thickness of the reversing material layer becomes more uniform.

### BRIEF DESCRIPTION OF THE DRAWINGS

FIG. 1 is a schematic cross-sectional view illustrating the relationship between the resist pattern coverage factor and the reversing material layer thickness;

FIGS. 2A to 2E are schematic process views illustrating the pattern forming method according to the first embodiment;

FIGS. 3A to 3F are schematic process views illustrating the pattern forming method according to a second embodiment;

FIGS. 4A to 4F are schematic process views illustrating the pattern forming method according to a third embodiment; and

FIG. 5 is a layout for illustrating the pattern forming system 200.

### DETAILED DESCRIPTION

In general, according to one embodiment, a pattern forming method includes: forming a film to be processed on a substrate; forming a resist pattern on the film to be processed; irradiating a predetermined portion of the resist pattern with an energy beam; forming a reversing material layer covering the resist pattern including the portion irradiated with the energy beam; forming a reversed pattern by removing the surface of the reversing material layer so as to expose the portion of the resist pattern not irradiated with the energy beam; removing the resist pattern; and performing an etching process on the film to be processed using the reversed pattern.

Embodiments will now be described with reference to the drawings. Note that the same numerals are applied to similar constituent elements in the drawings and detailed descriptions of such constituent elements are appropriately omitted.

### The First Embodiment

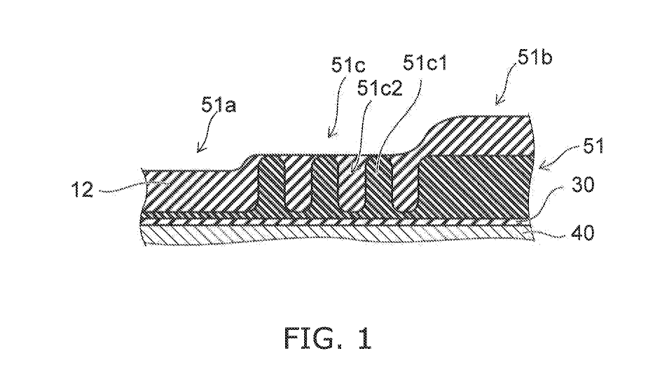

FIG. 1 is a schematic cross-sectional view illustrating the relationship between the resist pattern coverage factor and the reversing material layer thickness.

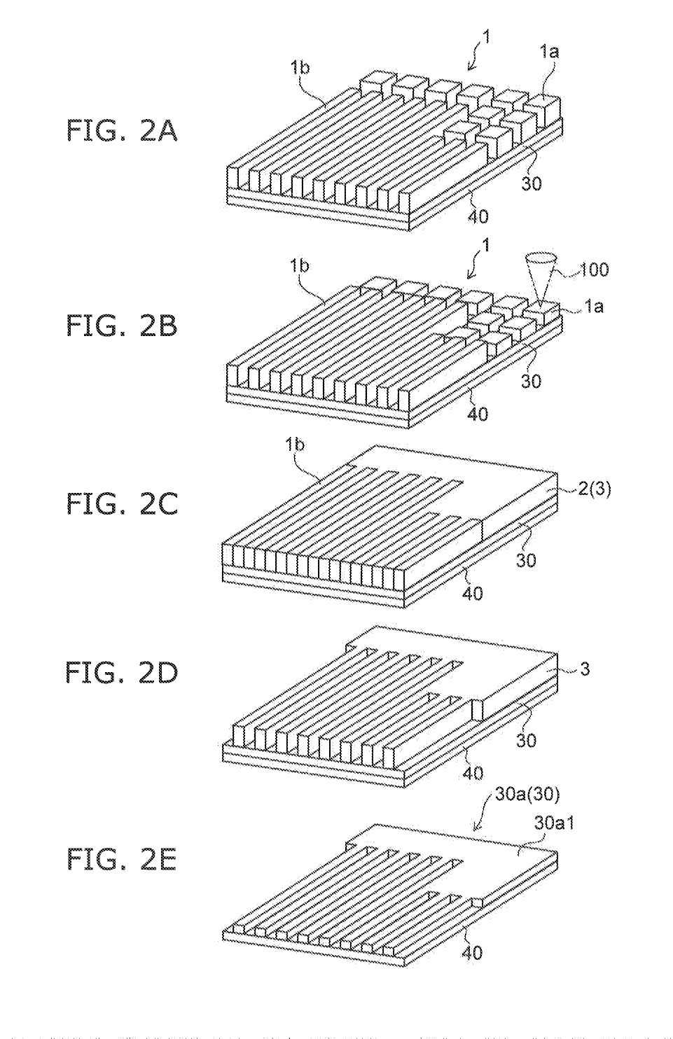

FIGS. 2A to 2E are schematic process views illustrating the pattern forming method according to the first embodiment.

As illustrated in FIG. 1, a film to be processed 30 is formed on a substrate 40. A resist pattern 51 for forming a reversed pattern is formed on the film to be processed 30.

In this case, an in-plane distribution in the coverage factor of the resist pattern 51 may be produced in accordance with the form of the reversed pattern to be formed.

For example, in a region 51a, there are no convex portions, so the coverage factor of the resist pattern 51 in the region 51a is 0%. In a region 51b, there are no concave portions, so the coverage factor of the resist pattern 51 in the region 51b is 100%. In a region 51c, there are concave portions 51c2 and convex portions 51c1, so the coverage factor of the resist pattern 51 in the region 51c is a value in accordance with the area ratio of concave portions 51c2 and convex portions 51c1.

When there is an in-plane distribution in the coverage factor of the resist pattern 51, the thickness of a reversing material layer 12 formed covering the resist pattern 51 is non-uniform.

Here, the reversing material that covers the region 51a is a portion of the reversed pattern. Therefore, it is necessary that the reversing material covering the region 51a will remain after removing the surface of the reversing material layer 12 (after etching-back).

The region 51b is an opening (concave portion) of the reversed pattern. Therefore, it is necessary that the reversing material that covers the region 51b will not remain after removing the surface of the reversing material layer 12.

Of the reversing material that covers the region 51c, the reversing material provided in the concave portions 51c2 is a portion of the reversed pattern. Therefore, it is necessary that the reversing material provided in the concave portions 51c2 will remain after removal of the surface of the reversing material layer 12. It is necessary that the reversing material that covers the top face of the convex portions 51c1 will not remain after removing the surface of the reversing material layer 12.

However, if the thickness of the reversing material layer 12 is non-uniform, when the surface of the reversing material layer 12 has been removed, there is a possibility that reversing material will remain in regions where the reversing material should be removed, and reversing material will be removed in regions where the reversing material should remain.

For example, when the reversing material that covers the top face of the convex portions 51c1 has been removed, if removal of the reversing material layer 12 is stopped, the reversing material that covers the region 51b will remain.

Also, when the reversing material that covers the region 51b is removed, if removal of the reversing material layer 12 is stopped, there is a possibility that the reversing material that covers the region 51a or the reversing material provided in the concave portions 51c2 will be removed.

Therefore, in the pattern forming method according to this embodiment, a dummy pattern 1a is disposed to reduce the in-plane distribution of the coverage factor of the resist pattern 1.

Here, the pattern forming method according to this embodiment is described using the example of a case of forming a pattern 30a as illustrated in FIG. 2E.

First, the film to be processed 30 that is the target of etching process is formed on the substrate 40.

The substrate 40 can be, for example, a glass substrate, a quartz substrate, a silicon substrate, or the like.

The substrate 40 is, for example, a substrate for an exposure mask, a mold for imprinting, a semiconductor substrate, and the like.

There is no particular limitation on the material of the film to be processed 30. For example, the material of the film to be processed 30 can be a light blocking material such as chromium or the like, an insulating material such as an oxide or a nitride, an electrically conducting material such as tungsten, copper, or the like, and the like.

There is no particular limitation on the thickness dimension of the film to be processed 30. The thickness dimension of the film to be processed 30 can be set as appropriate in accordance with the application and the like.

There is no particular limitation on the method of forming the film to be processed 30. For example, the film to be processed 30 can be formed using the chemical vapor deposition (CVD) method, the physical vapor deposition method (PVD) method, the thermal oxidation method, and the like.

Next, the resist pattern 1 is formed on the film to be processed 30, as illustrated in FIG. 2A.

The form of the resist pattern 1 is basically the reverse of the form of the pattern 30a. For example, the portion of the resist pattern 1 corresponding to a convex portion of the pattern 30a is a concave portion. The portion of the resist pattern 1 corresponding to a concave portion of the pattern 30a is a convex portion.

Therefore, as illustrated in FIG. 2E, when the pattern 30a has a large area convex portion 30a1 (continuous pattern face), a large area concave portion is provided in the portion of the resist pattern 1 corresponding to the convex portion 30a1. If a large area concave portion is provided in the resist pattern 1, the in-plane distribution of the coverage factor becomes large.

Therefore, the dummy pattern 1a is provided to reduce the in-plane distribution of the coverage factor of the resist pattern 1.

For example, the entire surface of the substrate 40 including dicing lines is divided into a plurality of regions with a predetermined size. Then, the dummy pattern 1a is disposed so that the coverage factor of the resist pattern 1 in each of the divided regions falls within ±10% of the coverage factor of the resist pattern 1 in any standard area.

The resist pattern 1 illustrated in FIG. 2A includes a line and space pattern element 1b (line portion) and the cuboidal shaped dummy pattern 1a.

The acceptable range of coverage factor, the shape, dimensions, arrangement, number, and the like of the element 1b and the dummy pattern 1a are not limited to those illustrated, but can be modified as appropriate.

The resist pattern 1 includes an organic material. The resist pattern 1 can be formed from an acrylic photocurable resin, for example.

There is no particular limitation on the method of forming the resist pattern 1 (the element 1b, the dummy pattern 1a). For example, the resist pattern 1 can be formed using a photolithography method, an imprint method, and the like.

Here, if the dummy pattern 1a is provided, it is possible to reduce the in-plane distribution of the coverage factor of the resist pattern 1, and thereby make the thickness of a reversing material layer 2 uniform.

However, normally, the height of the dummy pattern 1a is virtually the same as the height of the element 1b. Therefore, if the top face of the element 1b is exposed when removing the surface of the reversing material layer 2 as described later, the top face of the dummy pattern 1a will also be exposed. As a result, holes will be formed in the regions where the dummy pattern 1a is provided in a reversed pattern (reversed mask) 3, so it will not be possible to form the pattern 30a with the proper shape.

Therefore, in the pattern forming method according to this embodiment, the height of the dummy pattern 1a is lower than the height of the element 1b.

According to knowledge obtained by the inventors, if the top face of the dummy pattern 1a that includes an organic material is irradiated with an energy beam 100, the height of the dummy pattern 1a can be lowered by approximately 10% to 15%. Therefore, it is possible to prevent the top face of the dummy pattern 1a from being exposed when removing the surface of the reversing material layer 2.

Next, a predetermined portion of the resist pattern 1 is irradiated with the energy beam 100.

For example, as illustrated in FIG. 2B, the energy beam 100 is directed toward the top face of the dummy pattern 1a. The energy beam 100 can be, for example, an electron beam or an ion beam.

In this case, by controlling the positions irradiated with the energy beam 100, and controlling the relative position between an energy beam 100 irradiation device and the substrate 40, the top face of each of the dummy patterns 1a is irradiated with the energy beam 100.

As a result, the height of each of the dummy patterns 1a is lowered by approximately 10% to 15%.

Next, the reversing material layer 2 is formed covering the resist pattern 1 including the portion irradiated with the energy beam 100.

The reversing material layer 2 can be formed by applying reversing material.

There is no particular limitation on the method of application of the reversing material. The reversing material can be applied by, for example, spin coating.

The reversing material can include, for example, at least one of Si atoms, Ge atoms, Sn atoms, Ag atoms, Au atoms, and Ti atoms. The reversing material can be, for example, a photosensitive polysilane, a photosensitive polygermane, photosensitive polystannane, photosensitive polysilazane, photosensitive polysiloxane, photosensitive polycarbosilane, photopolymerizable silicon-containing acrylic monomer, silicon-containing novolak resin, silicon-containing poly-para-hydroxystyrene, copolymers of two or more of these compounds, and mixtures thereof.

Next, the surface of the reversing material layer 2 is removed so that the portion of the resist pattern 1 not irradiated with the energy beam 100 is exposed.

For example, as illustrated in FIG. 2C, the surface of the reversing material layer 2 is removed so that the element 1b of the reversed pattern 1 is exposed.

By removing the reversing material layer 2, the reversed pattern 3 is formed.

Removal of the surface of the reversing material layer 2 can be carried out using, for example, reactive ion etching (RIE).

The height of the dummy pattern 1a is lower than the height of the element 1b. Therefore, it is possible to remove the surface of the reversing material layer 2 so that the element 1b is exposed and the dummy pattern 1a is not exposed.

Next, the element 1b, which is the exposed portion of the resist pattern 1, is removed, as illustrated in FIG. 2D.

For example, the element 1b can be removed using a wet etching method or a dry etching method.

Next, the film to be processed 30 is etched using the reversed pattern 3 as an etching mask, and the pattern 30a is formed.

Next, the reversed pattern 3 is removed, as illustrated in FIG. 2E.

For example, the reversed pattern 3 can be removed by a wet ashing method or a dry ashing method.

In this way, the required pattern 30a can be formed.

### The Second Embodiment

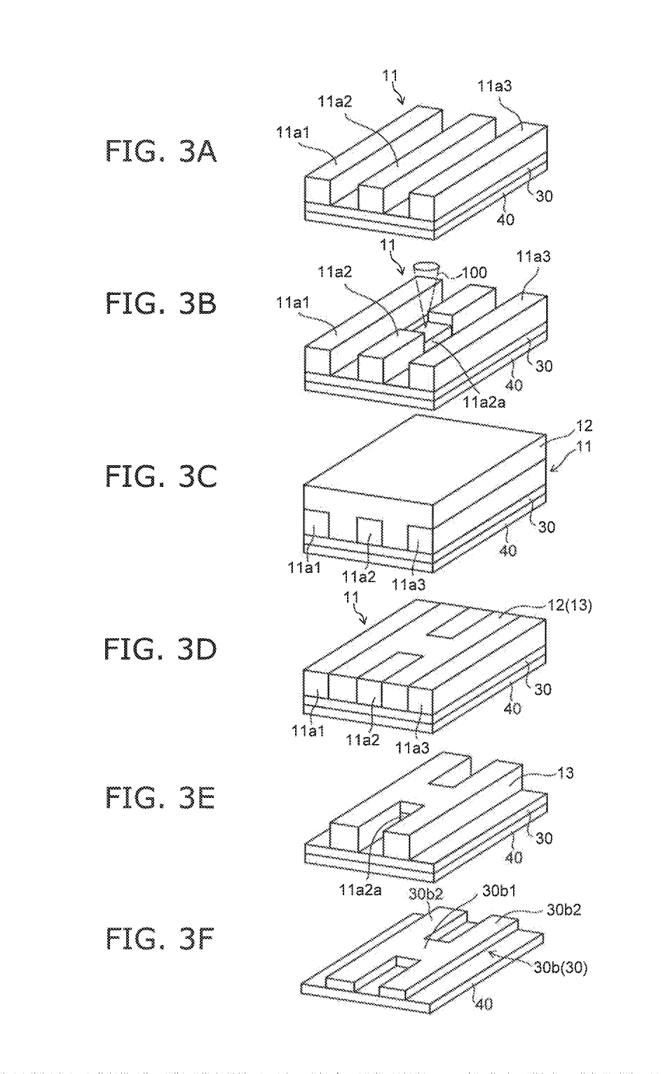

FIGS. 3A to 3F are schematic process views illustrating the pattern forming method according to a second embodiment.

The pattern forming method according to the second embodiment forms a pattern 30b as illustrated in FIG. 3F.

The form of a resist pattern 11 is basically the reverse of the form of the pattern 30b. However, in some cases, it is difficult to form the resist pattern 11 with the form of the pattern 30b reversed as it is, due to the limit of resolution of the exposure device.

Therefore, in the pattern forming method according to this embodiment, a portion to be modified is formed in the process of forming the resist pattern 1. Then, in the process of irradiating with the energy beam 100, the portion to be modified is irradiated with the energy beam 100.

Here, the portion to be modified is described as a portion 11a2a corresponding to an element 30b1 as illustrated in FIG. 3F. First, the resist pattern 11 is formed on the film to be processed 30, as illustrated in FIG. 3A.

The resist pattern 11 includes elements 11a1 to 11a3 corresponding to an element 30b2.

If the reversed pattern is formed using the resist pattern 11, the element 30b1 of the pattern 30b will not be formed, and the elements 30b2 only will be formed.

Therefore, next, the portion 11a2a of the resist pattern 11 corresponding to the element 30b1 is irradiated with the energy beam 100, and the height of the portion 11a2a is lowered, as illustrated in FIG. 3B.

In this case, the height of the portion 11a2a can be lowered by approximately 10% to 15%.

Next, the reversing material layer 12 is formed covering the resist pattern 11 including the portion 11a2a irradiated with the energy beam 100, as illustrated in FIG. 3C.

Next, the surface of the reversing material layer 12 is removed so that the portions of the resist pattern 11 not irradiated with the energy beam 100 (elements 11a1 to 11a3) are exposed, as illustrated in FIG. 3D.

By removing the reversing material layer 12, a reversed pattern 13 is formed.

In this case, the height of the portion 11a2a irradiated with the energy beam 100 is low, so it remains covered by the reversing material layer 12.

Next, the exposed portion of the resist pattern 11 is removed, as illustrated in FIG. 3E.

In this case, preferably, an anisotropic etching process such as RIE or the like is used. If the exposed portion of the resist pattern 11 is removed using an anisotropic etching process, it is possible to suppress the occurrence of indentations or the like due to removal of the side face of the portion 11a2a covered by the reversing material layer 12.

Next, the film to be processed 30 is etched using the reversed pattern 13 as an etching mask, and the pattern 30b is formed.

Next, the reversed pattern 13 is removed, as illustrated in FIG. 3F.

For example, the reversed pattern 13 can be removed by a wet ashing method or a dry ashing method.

In this way, the required pattern 30b can be formed.

### The Third Embodiment

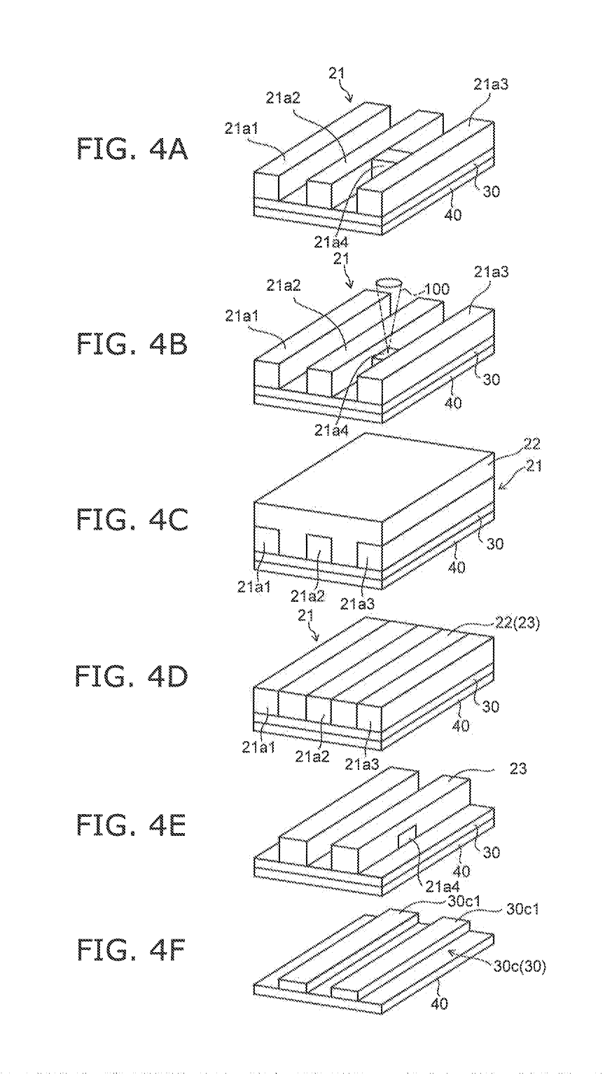

FIGS. 4A to 4F are schematic process views illustrating the pattern forming method according to a third embodiment.

The pattern forming method according to the third embodiment forms a pattern 30c as illustrated in FIG. 4F.

First, a resist pattern 21 is formed on the film to be processed 30, as illustrated in FIG. 4A.

The form of the resist pattern 21 is basically the reverse of the form of the pattern 30c.

The resist pattern 21 includes elements 21a1 to 21a3 corresponding to an element 30c1.

However, when forming the resist pattern 21, sometimes a short defect 21a4 occurs.

If the reversed pattern is formed using the resist pattern 21 having the short defect 21a4, the short defect 21a4 is transferred to the pattern 30c.

Therefore, a process of inspecting the resist pattern 21 is provided, and if a short defect 21a4 is detected, the short defect 21a4 is corrected as illustrated in FIG. 4B.

Inspection of the resist pattern 21 can be carried out by an optical defect inspection device using, for example, a short wavelength laser (for example, a solid-state second harmonic generation (SHG) laser with a wavelength of 193 nm).

As illustrated in FIG. 4B, the short defect 21a4 detected in the inspection of the resist pattern 21 is irradiated with the energy beam 100.

When the short defect 21a4 is irradiated with the energy beam 100, the height of the short defect 21a4 is lowered.

In this case, the height of the short defect 21a4 can be lowered by approximately 10% to 15%.

Next, a reversing material layer 22 is formed by applying reversing material covering the resist pattern 21, as illustrated in FIG. 4C.

Next, the surface of the reversing material layer 22 is removed so that the elements 21a1 to 21a3 of the resist pattern 21 are exposed, as illustrated in FIG. 4D.

By removing the surface of the reversing material layer 22, a reversed pattern 23 is formed.

In this case, the height of the short defect 21a4 is low, so it remains covered by the reversing material layer 22.

Next, the exposed portion of the resist pattern 21 is removed, as illustrated in FIG. 4E.

In this case, preferably, an anisotropic etching process such as RIE or the like is used. If the exposed portion of the resist pattern 21 is removed using an anisotropic etching process, it is possible to suppress the occurrence of indentations or the like due to removal of the side face of the short defect 21a4 covered by the reversing material layer 22.

Next, the film to be processed 30 is etched using the reversed pattern 23 as an etching mask, and the pattern 30a is formed.

Next, the reversed pattern 23 is removed, as illustrated in FIG. 4F.

For example, the reversed pattern 23 can be removed by a wet ashing method or a dry ashing method.

In this way, the required pattern 30c can be formed.

### The Fourth Embodiment

Next, a pattern forming system 200 is described.

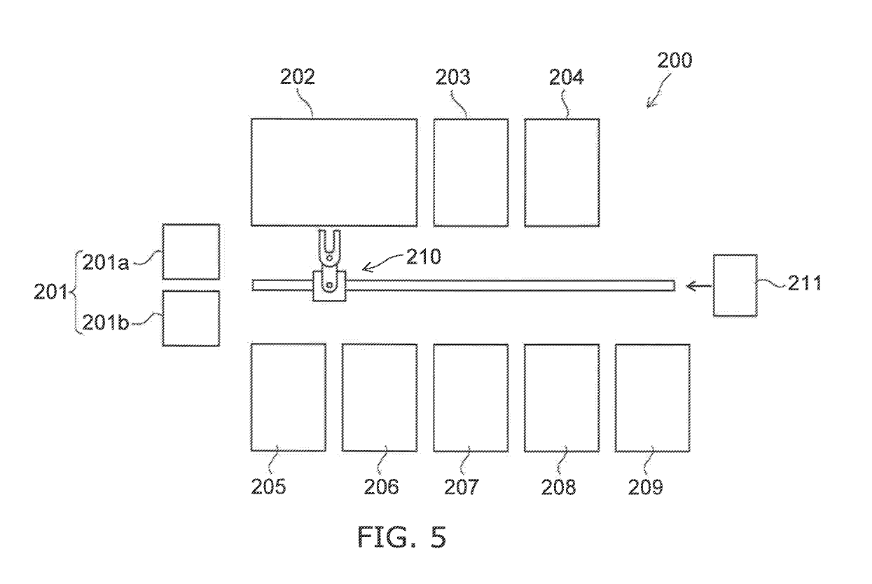

The pattern forming system 200 can execute the pattern forming method as described above. FIG. 5 illustrates a layout for illustrating the pattern forming system 200.

As illustrated in FIG. 5, a storage unit 201, a resist pattern forming unit 202, an inspection unit 203, an irradiation unit 204, a reversing material layer forming unit 205, a reversed pattern forming unit 206, a removal unit 207, an etching unit 208, a removal unit 209, a transport unit 210, and a control unit 211 are provided in the pattern forming system 200.

A commonly known film forming device that forms the film to be processed 30 on the substrate 40 can be further provided.

The storage unit 201 includes a storage unit 201a and a storage unit 201b.

The storage unit 201a stores a plurality of substrates 40 in the stacking direction. The storage unit 201a stores the substrates 40 before the pattern is formed. The film to be processed 30 is formed on the surface of the substrate 40 before the pattern is formed.

The storage unit 201b stores a plurality of substrates 40 in the stacking direction. The storage unit 201b stores the substrates 40 after the pattern is formed. Patterns 30a to 30c are formed on the surface of the substrate 40 after the patterns are formed.

The resist pattern forming unit 202 forms the resist pattern 1, 11, 21 on the film to be processed 30 provided on the substrate 40.

In this case, the dummy pattern is can be formed so that the in-plane distribution of the coverage factor of the resist pattern is reduced.

The resist pattern forming unit 202 includes an application device such as a spin coating device or the like, an exposure device, a developing device, a post-baking device, and the like.

Commonly known devices can be used for the application device, the exposure device, the developing device, the post-baking device, and the like, so their detailed description is omitted.

The inspection unit 203 inspects whether the resist pattern 1, 11, 21 has defects.

The inspection unit 203 can be an optical defect inspection device that includes, for example, a light source such as a mercury lamp or an argon laser or the like, a light focusing lens, an XY stage on which the substrate 40 on which the resist pattern 1, 11, 21 is formed is placed, an object lens, and an image sensor.

The irradiation unit 204 irradiates a specific portion of the resist pattern 1, 11, 21 with the energy beam 100.

For example, the irradiation unit 204 irradiates, for example, a dummy pattern 1a, a portion to be modified (portion 11a2a), a short defect 21a4 or the like with the energy beam 100.

For example, the irradiation unit 204 can be an electron beam irradiation device, an ion beam device, or the like.

The reversing material layer forming unit 205 forms the reversing material layer 2, 12, 22 by applying reversing material so as to cover the resist pattern 1, 11, 21. In other words, the reversing material layer forming unit 205 forms the reversing material layer 2, 12, 22 to cover the resist pattern 1, 11, 21 including the portion irradiated with the energy beam 100.

The reversing material layer forming unit 205 can be, for example, an application device such as a spin coating device or the like.

The reversed pattern forming unit 206 removes the surface of the reversing material layer 2, 12, 22 so that the portion of the resist pattern 1, 11, 21 not irradiated with the energy beam 100 is exposed.

By exposing the portion of the resist pattern 1, 11, 21 not irradiated with the energy beam 100, the reversed pattern 3, 13, 23 is formed.

The reversed pattern forming unit 206 can be, for example, a dry etching device such as an RIE device or the like, and the like.

The removal unit 207 removes the exposed portion of the resist pattern 1, 11, 21.

The removal unit 207 can be, for example, a dry etching device such as an RIE device of the like, or a wet ashing device, and the like.

The etching unit 208 carries out an etching process on the film to be processed 30 using the reversed pattern 3, 13, 23.

For example, the etching unit 208 etches the film to be processed 30 using the reversed pattern 3, 13, 23 as an etching mask, and the pattern 30a to 30c is formed.

The removal unit 209 removes the reversed pattern 3, 13, 23.

The removal unit 209 can be, for example, a dry etching device such as an RIE device or the like, or a wet ashing device, and the like.

The reversed pattern forming unit 206, the removal unit 207, and the removal unit 209 may be the same device.

The transport unit 210 transports the substrate 40 between the storage unit 201, the resist pattern forming unit 202, the inspection unit 203, the irradiation unit 204, the reversing material layer forming unit 205, the reversed pattern forming unit 206, the removal unit 207, the etching unit 208, and the removal unit 209.

The transport unit 210 can be, for example, a transport robot or the like.

The control unit 211 controls the operation of each of the elements provided in the storage unit 201, the resist pattern forming unit 202, the inspection unit 203, the irradiation unit 204, the reversing material layer forming unit 205, the reversed pattern forming unit 206, the removal unit 207, the etching unit 208, the removal unit 209, and the transport unit 210.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A pattern forming method, comprising: forming a film to be processed on a substrate;
forming a resist pattern on the film to be processed;
irradiating a predetermined portion of the resist pattern with an energy beam;
forming a reversing material layer covering the resist pattern including the portion irradiated with the energy beam;
forming a reversed pattern by removing the surface of the reversing material layer so as to expose the portion of the resist pattern not irradiated with the energy beam;
removing the resist pattern; and
performing an etching process on the film to be processed using the reversed pattern.

2. The method according to claim 1, wherein forming the resist pattern includes forming a dummy pattern, and
the irradiating with an energy beam includes irradiating the dummy pattern with the energy beam.

3. The method according to claim 2, wherein when forming the dummy pattern, the face of the substrate is divided into a plurality of regions of a predetermined size, and the dummy pattern is formed so that the coverage factor of the resist pattern in each of the divided regions falls within ±10% of the coverage factor of the resist pattern in any standard area.

4. The method according to claim 2, wherein when forming the dummy pattern, the dummy pattern is formed having the same height measurement as the height measurement of an element of the resist pattern.

5. The method according to claim 2, wherein the dummy pattern is irradiated with the energy beam, so that the height measurement of the dummy pattern is smaller than the height measurement of an element of the resist pattern.

6. The method according to claim 5, wherein when removing the surface of the reversing material layer, the element of the resist pattern not irradiated with the energy beam is exposed, and the dummy pattern irradiated with the energy beam is not exposed.

7. The method according to claim 4, wherein the element of the resist pattern is a line portion of a line and space pattern.

8. The method according to claim 1, wherein the forming the resist pattern includes forming a portion to be modified, and
the irradiating with an energy beam includes irradiating the portion to be modified with the energy beam.

9. The method according to claim 8, wherein when forming the portion to be modified, the portion to be modified is formed having the same height measurement as the height measurement of an element of the resist pattern.

10. The method according to claim 8, wherein the portion to be modified is irradiated with the energy beam, so that the height measurement of the portion to be modified is smaller than the height measurement of an element of the resist pattern.

11. The method according to claim 10, wherein when removing the surface of the reversing material layer, the element of the resist pattern not irradiated with the energy beam is exposed, and the portion to be modified irradiated with the energy beam is not exposed.

12. The method according to claim 1, further comprising inspecting the resist pattern, wherein
the irradiating with an energy beam includes irradiating with the energy beam a defect detected in the inspection of the resist pattern.

13. The method according to claim 12, wherein the defect is a short defect produced when forming the resist pattern.

14. The method according to claim 12, wherein the defect is irradiated with the energy beam, so that the height measurement of the defect is smaller than the height measurement of an element of the resist pattern.

15. The method according to claim 14, wherein when removing the surface of the reversing material layer, the element of the resist pattern not irradiated with the energy beam is exposed, and the defect irradiated with the energy beam is not exposed.

16. The method according to claim 15, wherein the removing the resist pattern includes removing the exposed element of the resist pattern using the RIE method.

17. The method according to claim 1, wherein the energy beam is an electron beam or an ion beam.

18. The method according to claim 1, wherein the reversing material layer includes at least one type of atom selected from the group consisting of Si atoms, Ge atoms, Sn atoms, Ag atoms, Au atoms, and Ti atoms.

19. The method according to claim 1, wherein the substrate is any of a substrate for an exposure mask, a mold for imprinting, and a semiconductor substrate.

20. A pattern forming system, comprising: a resist pattern forming unit that forms a resist pattern on a film to be processed provided on a substrate;
an irradiation unit that irradiates a predetermined portion of the resist pattern with an energy beam;
a reversing material layer forming unit that forms a reversing material layer that covers the resist pattern including the portion irradiated with the energy beam;
a reversed pattern forming unit that forms a reversed pattern by removing the surface of the reversing material layer so as to expose the portion of the resist pattern not irradiated with the energy beam;
a removal unit that removes the resist pattern; and
an etching unit that performs an etching process on the film to be processed using the reversed pattern.
